(19) United States
(12) Patent Application Publication
(10) Pub. No.: US 2024/0334684 A1
(43) Pub. Date: Oct. 3, 2024

(54) SEMICONDUCTOR MEMORY DEVICE

(71) Applicant: Samsung Electronics Co., Ltd., Suwon-si (KR)

(72) Inventors: Dongyoung Kim, Suwon-si (KR); Yoongoo Kang, Suwon-si (KR); Jaehong Park, Suwon-si (KR)

(21) Appl. No.: 18/536,334

(22) Filed: Dec. 12, 2023

(30) Foreign Application Priority Data
Mar. 28, 2023 (KR) 10-2023-0040162

(51) Int. Cl. H10B 12/00

(52) U.S. Cl. CPC H10B 12/485; H10B 12/482

(57) ABSTRACT

A semiconductor memory device includes an active pattern on a substrate and at least partially surrounded by a device isolation pattern, a bit line that extends on a center portion of the active pattern in a first direction that is parallel to a bottom surface of the substrate, and a bit line contact between the bit line and the active pattern. The bit line contact includes a metallic material. A width of the bit line contact at a first level and in a second direction is greater than a width of a bottom surface of the bit line contact in the second direction. The second direction intersects the first direction. The first level is between a top surface of the device isolation pattern and the substrate.

### CROSS-REFERENCE TO RELATED APPLICATIONS

This U.S. non-provisional patent application claims priority under 35 U.S.C. § 119 to Korean Patent Application No. 10-2023-0040162, filed on Mar. 28, 2023, in the Korean Intellectual Property Office, the entire contents of which are hereby incorporated by reference.

### TECHNICAL FIELD

The present disclosure relates to a semiconductor device, and in particular, to a semiconductor memory device.

### BACKGROUND

Due to their small-sized, multifunctional, and/or low-cost characteristics, semiconductor devices are ubiquitous in the electronics industry. The semiconductor devices are classified into semiconductor memory devices for storing data, semiconductor logic devices for processing data, and hybrid semiconductor devices including both memory and logic elements.

Due to the recent increasing demand for electronic devices with a high speed and/or low power consumption, fast operating speeds and/or a low operating voltages may be desired. To achieve these characteristics, it may be desirable to increase an integration density of the semiconductor device. As the integration density of the semiconductor device increases, the electrical and reliability characteristics of the semiconductor device may not increase. Accordingly, many studies are being conducted to improve the electrical and reliability characteristics of the semiconductor device.

### SUMMARY

An embodiment of the present disclosure provides a semiconductor memory device with improved electrical and reliability characteristics.

According to an embodiment of the present disclosure, a semiconductor memory device may include an active pattern on a substrate and at least partially surrounded by a device isolation pattern, a bit line that extends on a center portion of the active pattern in a first direction that is parallel to a bottom surface of the substrate, and a bit line contact between the bit line and the active pattern. The bit line contact may include a metallic material. A width of the bit line contact at a first level and in a second direction is greater than a width of a bottom surface of the bit line contact in the second direction. The second direction intersects the first direction. The first level is between a top surface of the device isolation pattern and the substrate.

According to an embodiment of the present disclosure, a semiconductor memory device may include an active pattern on a substrate and at least partially surrounded by a device isolation pattern, a bit line that extends on a center portion of the active pattern in a first direction that is parallel to a bottom surface of the substrate, and a bit line contact between the bit line and the active pattern, the bit line contact including a metallic material and including an upper portion and a lower portion. The upper portion and the lower portion contact each other at a first level. A width of the upper portion at the first level and in a second direction is greater than a width of the lower portion at the first level and in the second direction that intersects the first direction.

According to an embodiment of the present disclosure, a semiconductor memory device may include an active pattern on a substrate and at least partially surrounded by a device isolation pattern, a bit line that extends on a center portion of the active pattern in a first direction that is parallel to a bottom surface of the substrate, and a bit line contact between the bit line and the active pattern. The bit line contact may include a metallic material. A width of the bit line contact at a first level and in a second direction is greater than a width of each of bottom and top surfaces of the bit line contact the second direction, which intersects the first direction.

### BRIEF DESCRIPTION OF THE DRAWINGS

FIG. 1 is a block diagram illustrating a semiconductor memory device according to an embodiment of the present disclosure.

FIG. 2 is a plan view illustrating a portion (e.g., P1 of FIG. 1) of a semiconductor memory device according to an embodiment of the present disclosure.

FIGS. 3A and 3B are sectional views, which are respectively taken along lines A-A′ and B-B′ of FIG. 2, that illustrate a semiconductor memory device according to an embodiment of the present disclosure.

FIG. 4 is an enlarged sectional view corresponding to a portion P2 of FIG. 3A.

FIG. 5 is an enlarged sectional view corresponding to the portion P2 of FIG. 3A.

FIG. 6 is a sectional view, which is taken along the line A-A′ of FIG. 2, that illustrates a semiconductor memory device according to an embodiment of the present disclosure.

FIG. 7 is an enlarged sectional view corresponding to a portion P3 of FIG. 6.

FIGS. 8, 9, 10, 11, 12, and 13 are sectional views illustrating a method of fabricating a semiconductor memory device according to an embodiment of the present disclosure.

FIGS. 14 and 15 are sectional views illustrating a method of fabricating a semiconductor memory device according to an embodiment of the present disclosure.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. As used herein, “an element A is at a same level as element B” refers to at least one surface of element A that is coplanar with at least one surface of element B. The term “connected” may be used herein to refer to a physical and/or electrical connection and may refer to a direct or indirect physical and/or electrical connection.

Example embodiments of the present disclosures will now be described more fully with reference to the accompanying drawings, in which example embodiments are shown.

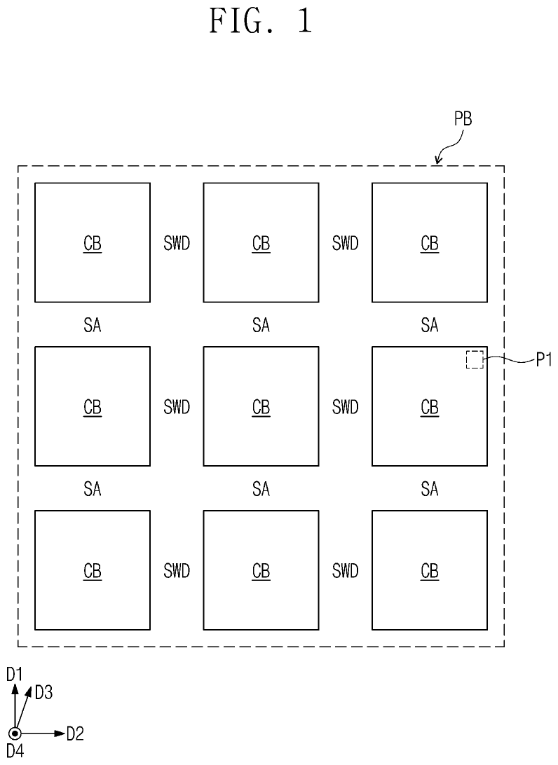

FIG. 1 is a block diagram illustrating a semiconductor memory device according to an embodiment of the present disclosure.

Referring to FIG. 1, a semiconductor memory device may include cell blocks CB and a peripheral block PB, which surrounds each of the cell blocks CB. Each of the cell blocks CB may include a cell circuit, such as a memory integrated circuit. The peripheral block PB may include various peripheral circuits, which operate the cell circuit, and the peripheral circuits may be electrically connected to the cell circuit.

The peripheral block PB may include sense amplifier circuits SA and sub-word line driver circuits SWD. In an embodiment, the sense amplifier circuits SA may face each other, with the cell blocks CB interposed therebetween, and the sub-word line driver circuits SWD may face each other, with the cell blocks CB interposed therebetween. The peripheral block PB may further include power and ground circuits, which drive a sense amplifier circuit SA, but the present disclosure is not limited to this example.

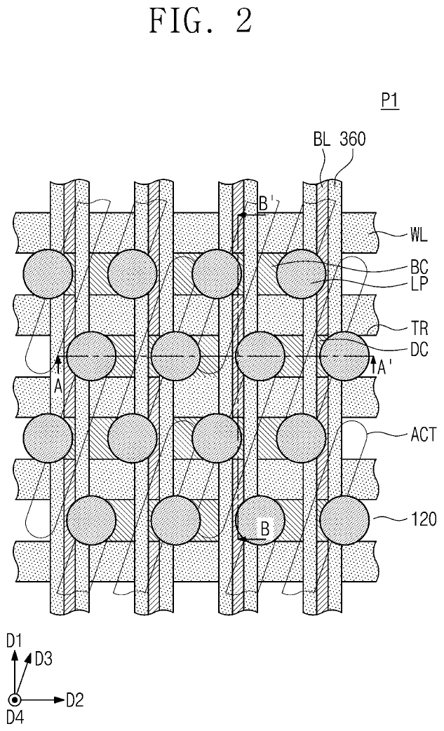

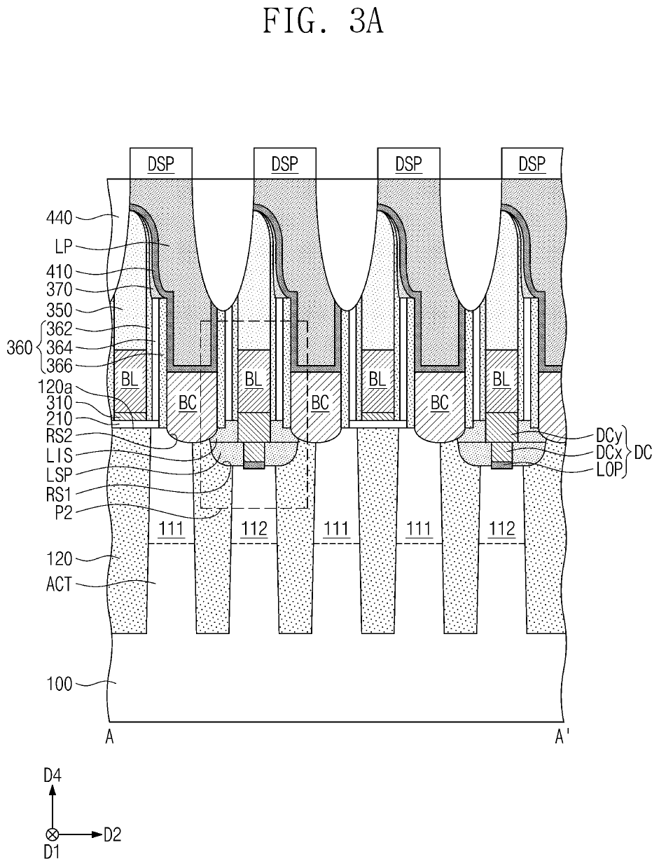

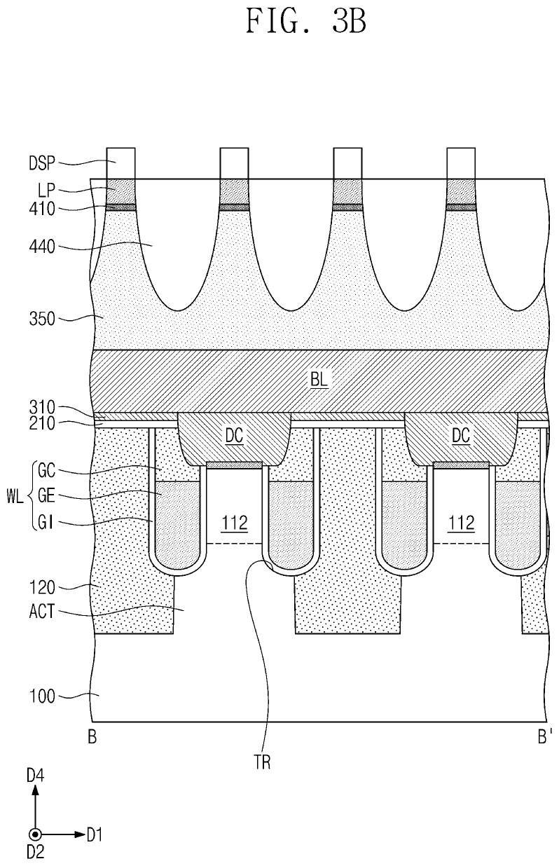

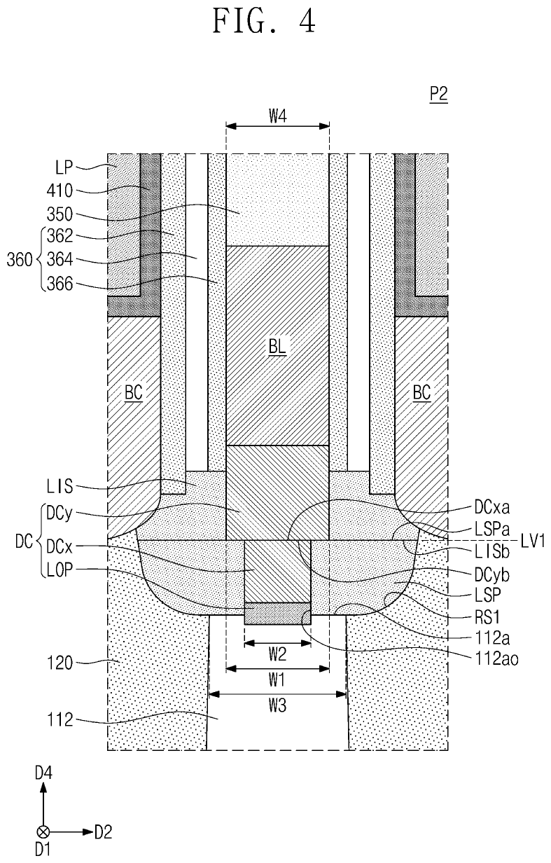

FIG. 2 is a plan view illustrating a portion (e.g., P1 of FIG. 1) of a semiconductor memory device according to an embodiment of the present disclosure. FIGS. 3A and 3B are sectional views, which are respectively taken along lines A-A′ and B-B′ of FIG. 2, that illustrate a semiconductor memory device according to an embodiment of the present disclosure. FIG. 4 is an enlarged sectional view corresponding to a portion P2 of FIG. 3A.

Referring to FIGS. 2 to 4, a substrate 100 may be provided. The substrate 100 may be a semiconductor substrate (e.g., a silicon wafer, a germanium wafer, or a silicon-germanium wafer).

A device isolation pattern 120 may be on the substrate 100 and define active patterns ACT. The active patterns ACT may be on the cell blocks CB of FIG. 1. The active patterns ACT may be spaced apart from each other in a first direction D1 and a second direction D2, which are non-parallel (e.g., perpendicular) to each other. The first direction D1 and the second direction D2 may be parallel to a bottom surface of the substrate 100. The active patterns ACT may be bar-shaped patterns, which are spaced apart from each other and are elongated in a third direction D3. The third direction D3 may be parallel to the bottom surface of the substrate 100 and may be non-parallel to the first and second directions D1 and D2.

The active patterns ACT may extend in a fourth direction D4 perpendicular to the bottom surface of the substrate 100. In an embodiment, the device isolation pattern 120 may be in the substrate 100, and the active patterns ACT may be portions of the substrate 100 enclosed by the device isolation pattern 120. In the present specification, the term “substrate 100” may refer to the remaining portion of the substrate 100, excluding the active patterns ACT, unless otherwise stated, for the sake of convenience in explanation.

The device isolation pattern 120 may be formed of or include at least one insulating material (e.g., silicon oxide and silicon nitride). The device isolation pattern 120 may be a single layer, which is made of a single material, or a composite layer including two or more materials. In the present specification, each of the expressions of “A or B”, “at least one of A and B”, “at least one of A or B”, “A, B, or C”, “at least one of A, B, and C”, and “at least one of A, B, or C” may be used to represent one of the elements enumerated in the expression or any possible combination of the enumerated elements.

Each of the active patterns ACT may include a pair of edge portions 111 and a center portion 112. The pair of edge portions 111 may be opposite end portions of the active pattern ACT in the third direction D3. The center portion 112 may be a portion of the active pattern ACT, which is interposed between the paired edge portions 111, specifically, between a pair of word lines WL that will be described below. The pair of edge portions 111 and/or the center portion 112 may be doped with impurities to have an n- or p-type conductivity.

The word line WL may intersect the active patterns ACT. In an embodiment, the word line WL may intersect the active patterns ACT and the device isolation pattern 120 in the second direction D2. In an embodiment, a plurality of word lines WL may be provided. The word lines WL may be spaced apart from each other in the first direction D1. A pair of the word lines WL, which are adjacent to each other in the first direction D1, may intersect one active pattern ACT. Each of the word lines WL may be placed in each of trench regions TR, which are formed in the active patterns ACT and the device isolation pattern 120.

Each of the word lines WL may include a gate electrode GE, a gate dielectric pattern GI, and a gate capping pattern GC. The gate electrode GE may extend through the active patterns ACT and the device isolation pattern 120 in the second direction D2. The gate dielectric pattern GI may be interposed between the gate electrode GE and the active patterns ACT and between the gate electrode GE and the device isolation pattern 120. The gate capping pattern GC may be on the gate electrode GE and cover a top surface of the gate electrode GE. The gate electrode GE may be formed of or include at least one metallic material (e.g., Ti, Mo, W, Cu, Al, Ta, Ru, and Ir). The gate dielectric pattern GI may be formed of or include at least one of silicon oxide or high-k dielectric materials. In the present specification, the high-k dielectric material may be defined as a material having a dielectric constant higher than silicon oxide. The gate capping pattern GC may include silicon nitride.

A buffer pattern 210 may be on the substrate 100. The buffer pattern 210 may be on and/or cover the active patterns ACT, the device isolation pattern 120, and the word lines WL. In an embodiment, the buffer pattern 210 may be formed of or include at least one of silicon oxide, silicon nitride, or silicon oxynitride.

First recess regions RS1 may be in an upper portion of each of the active patterns ACT and an upper portion of the device isolation pattern 120 adjacent thereto.

A bit line BL may be on the device isolation pattern 120 and the active patterns ACT. In an embodiment, a plurality of bit lines BL may be provided. The bit lines BL may extend in the first direction D1 and may be spaced apart from each other in the second direction D2. The bit line BL may be formed of or include at least one metallic material (e.g., Ti, Mo, W, Cu, Al, Ta, Ru, and Ir).

A bit line contact DC may be on the first recess region RS1. The bit line contact DC may be connected to the center portion 112 of the active pattern ACT. The bit line contact DC may be interposed between the active pattern ACT and the corresponding bit line BL. The bit line contact DC may electrically connect the corresponding bit line BL to the center portion 112 of the active pattern ACT. The bit line contact DC may be formed of or include at least one of doped or undoped polysilicon or metallic materials (e.g., Ti, Mo, W, Cu, Al, Ta, Ru, and Ir). In an embodiment, the bit line contact DC may be formed of or include at least one of Ti or TiN.

In an embodiment, a plurality of the bit line contacts DC may be on the active patterns ACT. Each of the bit line contacts DC may be connected to the center portion 112 of each of the active patterns ACT. The bit line contacts DC may be spaced apart from each other in the first and second directions D1 and D2. The bit line contacts DC may be respectively interposed between the active patterns ACT and the bit lines BL. Each of the bit line contacts DC may electrically connect a corresponding one of the bit lines BL to the center portion 112 of a corresponding one of the active patterns ACT.

The bit line contact DC may include an upper portion DCy and a lower portion DCx. The upper portion DCy of the bit line contact DC may be defined as a portion of the bit line contact DC, which is located at a level higher than a first level LV1. The lower portion DCx of the bit line contact DC may be defined as another portion of the bit line contact DC that is located at a level lower than the first level LV1. In an embodiment, the first level LV1 may be a level that is between a top surface 120a of the device isolation pattern 120 and the substrate 100. The upper portion DCy of the bit line contact DC may be in contact with the lower portion DCx of the bit line contact DC at the first level LV1. A top surface of the upper portion DCy of the bit line contact DC may be coplanar with a top surface of a polysilicon pattern 310, which will be described below. As an example, the lower portion DCx of the bit line contact DC may be located at a level lower than a top surface of the device isolation pattern 120.

As used herein, “an element A is at a lower level than element B” or “an element A is located at a level lower than element B” refers to a surface of element A that extends from the substrate 100 by a first distance that is less than a second distance in which element B extends from the substrate 100. As used herein, “an element A is at a higher level than element B” or “an element A is located at a level higher than element B” refers to a surface of element A that extends from the substrate 100 by a first distance that is greater than a second distance in which element B extends from the substrate 100.

When measured at the first level LV1, the upper portion DCy of the bit line contact DC may have a first width W1 in the second direction D2, and the lower portion DCx may have a second width W2 in the second direction D2. The first width W1 may be larger than the second width W2. The first width W1 may be larger than a width of a bottom surface of the bit line contact DC (i.e., a width of a bottom surface of the lower portion DCx of the bit line contact DC). The first width W1 may be smaller than a third width W3 of the uppermost surface 112a of the center portion 112 of the active pattern ACT in the second direction D2. The first width W1 may be substantially equal to or larger than a fourth width W4 of a top surface of the bit line BL in the second direction D2. A width of a top surface of the bit line contact DC (e.g., a top surface of the upper portion DCy of the bit line contact DC) in the second direction D2 may be larger than the second width W2.

According to an embodiment of the present disclosure, the bit line contact DC may be formed of or include a metallic material having lower resistivity than polysilicon, and thus, it may have a relatively small resistance value. As a result, even when the bit line contact DC has a small width, the semiconductor memory device may have improved electrical characteristics.

A lower ohmic pattern LOP may be on the active pattern ACT. In an embodiment, the lower ohmic pattern LOP may be interposed between the lower portion DCx of the bit line contact DC and the active pattern ACT. The bit line contact DC and the active pattern ACT may form an ohmic contact due to the lower ohmic pattern LOP. A bottom surface of the lower ohmic pattern LOP may be located at a level lower than the uppermost surface 112a of the center portion 112 of the active pattern ACT. A top surface of the lower ohmic pattern LOP may be located at a level higher than the uppermost surface 112a of the center portion 112 of the active pattern ACT. The lower ohmic pattern LOP may be interposed between a pair of the word lines WL, which are adjacent to each other in the first direction D1. The lower ohmic pattern LOP may be formed of or include at least one of metal silicide materials (e.g., silicide materials containing Ti, Mo, W, Cu, Al, Ta, Ru, and Ir).

A lower spacer LSP may be on the first recess region RS1. In an embodiment, the lower spacer LSP may fill a portion (e.g., a lower portion) of the first recess region RS1 and may be on and/or cover a side surface of the lower portion DCx of the bit line contact DC. A bottom surface DCyb of the upper portion DCy of the bit line contact DC may be on and/or cover a portion of a top surface of the lower spacer LSP. In an embodiment, the lower spacer LSP may be on and/or cover at least a portion of an inner surface of the first recess region RS1 (e.g., placed at a level lower than the first level LV1). In an embodiment, the lower spacer LSP may be on and/or cover at least a portion (e.g., an upper portion) of a side surface of the lower ohmic pattern LOP. A portion of the lower spacer LSP may vertically overlap with the center portion 112 of the active pattern ACT. A width of the lower spacer LSP in the second direction D2 may decrease toward the substrate 100. The lower spacer LSP may be formed of or include at least one of SiN, SiOCN, SiO2, SiOC, or SiBN.

In an embodiment, a top surface LSPa of the lower spacer LSP may be located at a first level LV1. As an example, the lower spacer LSP may contact the bottom surface DCyb of the upper portion DCy of the bit line contact DC. The top surface LSPa of the lower spacer LSP may be coplanar with a top surface DCxa of the lower portion DCx of the bit line contact DC. The top surface LSPa of the lower spacer LSP may be located at a level lower than the top surface 120a of the device isolation pattern 120.

A lower insulating pattern LIS may be on the top surface of the lower spacer LSP. The lower insulating pattern LIS may fill a portion (e.g., an upper portion) of the first recess region RS1 and may be on and/or cover a portion of a side surface of the upper portion DCy of the bit line contact DC. In an embodiment, the lower insulating pattern LIS may be on and/or cover at least a portion of inner surface of the first recess region RS1 (e.g., placed at a level higher than the first level LV1). The lower insulating pattern LIS may be formed of or include at least one of silicon oxide or silicon nitride.

In an embodiment, a bottom surface LISb of the lower insulating pattern LIS may be located at the first level LV1. The bottom surface LISb of the lower insulating pattern LIS may contact the top surface LSPa of the lower spacer LSP at the first level LV1.

The polysilicon pattern 310 may be between the bit line BL and the buffer pattern 210. In an embodiment, a top surface of the polysilicon pattern 310 may be located at substantially the same level as a top surface of the bit line contact DC. The polysilicon pattern 310 may be formed of or include polysilicon. In an embodiment, a first ohmic pattern (not shown) may be between the polysilicon pattern 310 and the bit line BL. The first ohmic pattern may be formed of or include at least one metal silicide material (e.g., silicide materials containing Ti, Mo, W, Cu, Al, Ta, Ru, and Ir).

A first barrier pattern (not shown) may be between the bit line BL and the bit line contact DC and between the bit line BL and the polysilicon pattern 310. The first barrier pattern may prevent or suppress a metallic material in the bit line BL from being diffused into the polysilicon pattern 310. The first barrier pattern may be formed of or include at least one conductive metal nitride material (e.g., nitride materials containing Ti, Mo, W, Cu, Al, Ta, Ru, and Ir).

A bit line capping pattern 350 may be on the top surface of the bit line BL. In an embodiment, a plurality of bit line capping patterns 350 may be provided. Each of the bit line capping pattern 350 may extend along a corresponding one of the bit lines BL and in the first direction D1 and may be spaced apart from each other in the second direction D2. The bit line capping pattern 350 may vertically overlap with the bit line BL. The bit line capping pattern 350 may include a single layer or a plurality of layers. In an embodiment, the bit line capping pattern 350 may include three or more sub-capping patterns, which are sequentially stacked. The bit line capping pattern 350 may be formed of or include silicon nitride.

A bit line spacer 360 may be on a side surface of the bit line BL and a side surface of the bit line capping pattern 350. The bit line spacer 360 may cover the side surface of the bit line BL and the side surface of the bit line capping pattern 350. In an embodiment, a plurality of bit line spacers 360 may be provided. As an example, a pair of bit line spacers 360 may be on and cover opposite side surfaces of the bit line BL.

The bit line spacer 360 may include a plurality of spacers. As an example, the bit line spacer 360 may include a first spacer 362, a second spacer 364, and a third spacer 366. The third spacer 366 may be on the side surface of the bit line BL and the side surface of the bit line capping pattern 350. The first spacer 362 may be interposed between the bit line BL and the third spacer 366 and between the bit line capping pattern 350 and the third spacer 366. The second spacer 364 may be interposed between the first spacer 362 and the third spacer 366. As an example, each of the first to third spacers 362, 364, and 366 may be formed of or include at least one of silicon nitride, silicon oxide, or silicon oxynitride. As another example, the second spacer 364 may include an air gap separating the first and third spacers 362 and 366 from each other.

A capping spacer 370 may be on the bit line spacer 360. The capping spacer 370 may be on and/or cover an upper portion of a side surface of the bit line spacer 360. The capping spacer 370 may be formed of or include silicon nitride.

A storage node contact BC may be between adjacent ones of the bit lines BL. In an embodiment, a plurality of storage node contacts BC may be provided. The storage node contacts BC may be spaced apart from each other in the first and second directions D1 and D2. The storage node contacts BC, which are adjacent to each other in the first direction D1, may be spaced apart from each other with the bit line BL interposed therebetween. The storage node contacts BC, which are adjacent to each other in the second direction D2, may be spaced apart from each other with a fence pattern (not shown) interposed therebetween. Each of the storage node contacts BC may be provided to fill a second recess region RS2, which is formed on a corresponding one of the edge portions 111 of the active patterns ACT, and may be connected to the corresponding edge portion 111. In an embodiment, the storage node contact BC may be formed of or include at least one of doped or undoped polysilicon or metallic materials (e.g., Ti, Mo, W, Cu, Al, Ta, Ru, and Ir).

On the word lines WL, fence patterns may separate the storage node contacts BC from each other in the first direction D1. In an embodiment, the fence patterns may be adjacent to each other in the first direction D1, with the storage node contacts BC interposed therebetween. The fence patterns may be formed of or include silicon nitride.

A second barrier pattern 410 may be on and/or conformally cover the bit line spacer 360 and the storage node contact BC. The second barrier pattern 410 may be formed of or include at least one conductive metal nitride material (e.g., nitride materials containing Ti, Mo, W, Cu, Al, Ta, Ru, and Ir). A second ohmic pattern (not shown) may be further interposed between the second barrier pattern 410 and the storage node contact BC. The second ohmic pattern may be formed of or include at least one metal silicide material (e.g., silicide materials containing Ti, Mo, W, Cu, Al, Ta, Ru, and Ir).

A landing pad LP may be on the storage node contact BC. In an embodiment, a plurality of landing pads LP may be provided, and here, the landing pads LP may be spaced apart from each other in the first and second directions D1 and D2. Each of the landing pads LP may be connected to a corresponding one of the storage node contacts BC. The landing pad LP may be on and/or cover a top surface of the bit line capping pattern 350. As an example, a lower region of the landing pad LP may vertically overlap with the storage node contact BC. As another example, an upper region of the landing pad LP may be shifted from the lower region in the second direction D2. The landing pad LP may be formed of or include at least one metallic material (e.g., Ti, Mo, W, Cu, Al, Ta, Ru, and Ir).

A filler pattern 440 may at least partially surround or enclose the landing pad LP. The filler pattern 440 may be interposed between adjacent ones of the landing pads LP. When viewed in a plan view, the filler pattern 440 may be provided as a mesh shape with holes, and in this case, the landing pads LP may be provided in the holes to extend through the filler pattern 440. As an example, the filler pattern 440 may be formed of or include at least one of silicon nitride, silicon oxide, or silicon oxynitride. Alternatively, the filler pattern 440 may include an empty space with an air layer (i.e., an air gap).

A data storage pattern DSP may be on the landing pad LP. In an embodiment, a plurality of data storage patterns DSP may be provided, and the data storage patterns DSP may be spaced apart from each other in the first and second directions D1 and D2. The data storage patterns DSP may be connected to the edge portions 111, respectively, via corresponding landing pads LP and corresponding storage node contacts BC.

In an embodiment, the data storage pattern DSP may be a capacitor including a bottom electrode, a dielectric layer, and a top electrode. In this case, the semiconductor memory device according to an embodiment of the present disclosure may be a dynamic random access memory (DRAM) device. In an embodiment, the data storage pattern DSP may include a magnetic tunnel junction pattern. In this case, the semiconductor memory device may be a magnetic random access memory (MRAM) device. In an embodiment, the data storage pattern DSP may be formed of or include a phase-change material or a variable resistance material. In this case, the semiconductor memory device may be a phase-change random access memory (PRAM) device or a resistive random access memory (ReRAM) device. However, the present disclosure is not limited to these examples, and the data storage pattern DSP may include various structures and/or materials that store data.

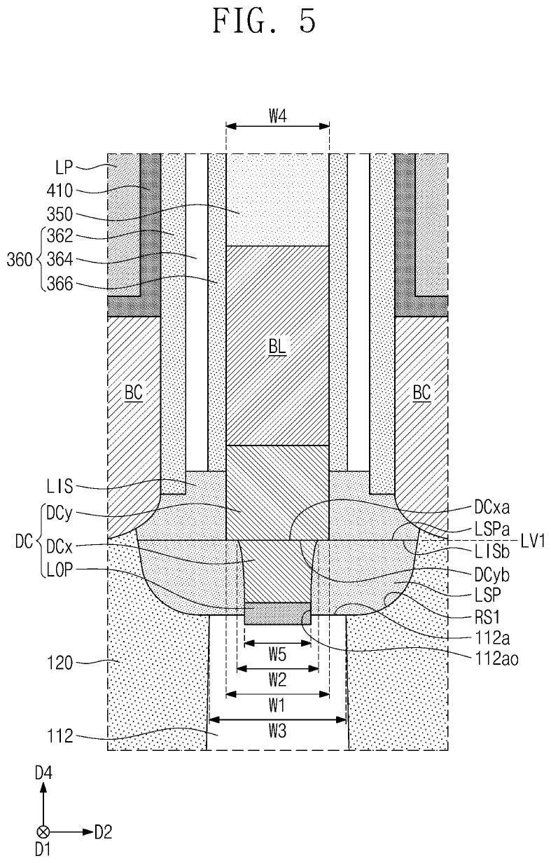

FIG. 5 is an enlarged view illustrating a portion (e.g., P2 of FIG. 3A) of a semiconductor memory device according to an embodiment of the present disclosure. A semiconductor memory device according to an embodiment of the present disclosure will be described in more detail with reference to FIG. 5. For concise description, a previously-described element may be identified by the same reference number without repeating an overlapping description thereof.

Referring to FIG. 5, the lower portion DCx of the bit line contact DC may have a fifth width W5, when measured in the second direction D2 at its bottom surface. In an embodiment, the second width W2 may be larger than the fifth width W5. The second width W2 may be substantially equal to or smaller than the first width W1. In an embodiment, the side surface of the lower portion DCx of the bit line contact DC in the second direction D2 may be a curved surface.

An inner side surface of the lower spacer LSP may be a curved surface on and/or covering the side surface of the lower portion DCx of the bit line contact DC. In an embodiment, the curved surface may be convex from an inner portion of the lower spacer LSP toward the bit line contact DC. In the case where the widths W1 and W2 of the upper and lower portions DCy and DCx of the bit line contact DC at the first level LV1 have the same value, the top surface LSPa of the lower spacer LSP may not contact the bottom surface DCyb of the upper portion DCy of the bit line contact DC.

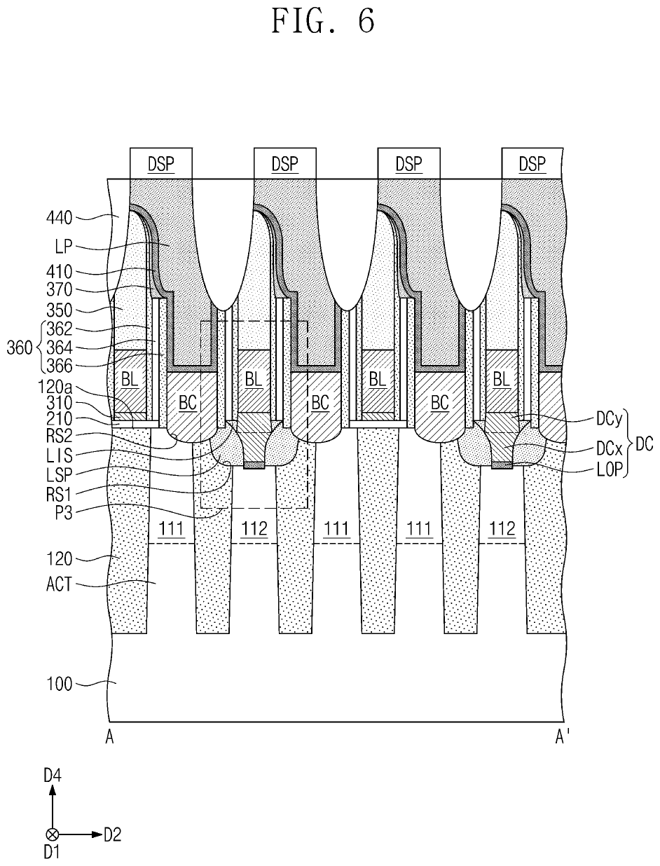

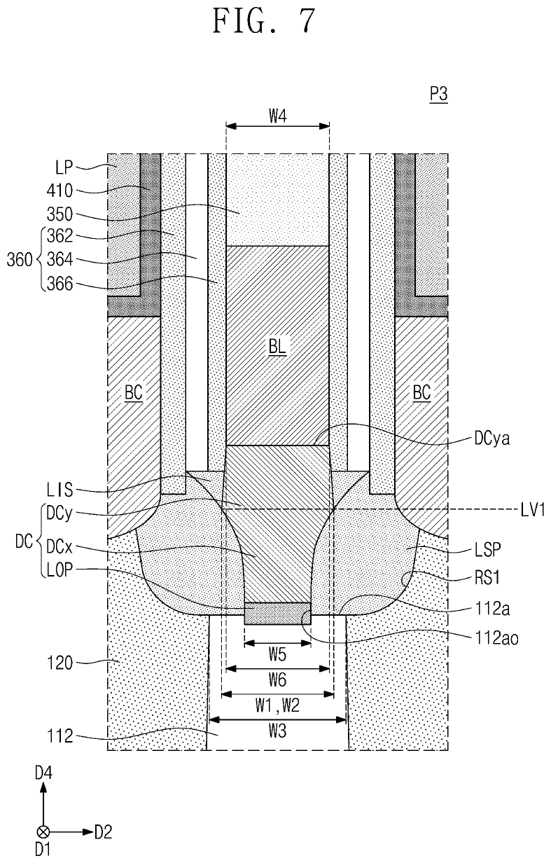

FIG. 6 is a sectional view, which is taken along the line A-A′ of FIG. 2 to illustrate a semiconductor memory device according to an embodiment of the present disclosure. FIG. 7 is an enlarged sectional view corresponding to a portion P3 of FIG. 6. A semiconductor memory device according to an embodiment of the present disclosure will be described in more detail with reference to FIGS. 6 and 7. For concise description, a previously-described element may be identified by the same reference number without repeating an overlapping description thereof.

Referring to FIGS. 6 and 7, a width of the bit line contact DC in the second direction D2 may decrease as a distance from the first level LV1 increases in upward and downward directions. In an embodiment, the first width W1 may be substantially equal to the second width W2. The bit line contact DC at a level of its top surface may have a sixth width W6 in the second direction D2. Each of the first and second widths W1 and W2 may be larger than the fifth and sixth widths W5 and W6. Each of the first and second widths W1 and W2 may be smaller than the third width W3 of the uppermost surface 112a of the center portion 112 of the active pattern ACT in the second direction D2. Each of the first and second widths W1 and W2 may be larger than the fourth width W4 of the top surface of the bit line BL in the second direction D2.

A side surface of the bit line contact DC, which is placed at a level lower than the first level LV1, may be a curved surface. In an embodiment, the curved surface may be convex toward an inner portion of the bit line contact DC.

The lower spacer LSP may fill the first recess region RS1 and may be on and/or cover a portion of the side surface of the bit line contact DC that is lower than the first level LV1. The lower spacer LSP may be spaced apart from another portion of the side surface of the bit line contact DC by the lower insulating pattern LIS. The lower spacer LSP may be located at a level lower than a top surface of the buffer pattern 210. The inner side surface of the lower spacer LSP may be a curved surface. In an embodiment, the curved surface may be convex from the inner portion of the lower spacer LSP toward the bit line contact DC.

The lower insulating pattern LIS may be on the top surface of the lower spacer LSP. In an embodiment, the lower spacer LSP may contact the lower insulating pattern LIS at a level higher than the first level LV1. The lower insulating pattern LIS may be on and/or cover another portion of the side surface of the bit line contact DC at a level higher than the first level LV1. In an embodiment, the lower insulating pattern LIS may be interposed between an upper portion of the lower spacer LSP and the bit line contact DC, which are adjacent to each other in the second direction D2.

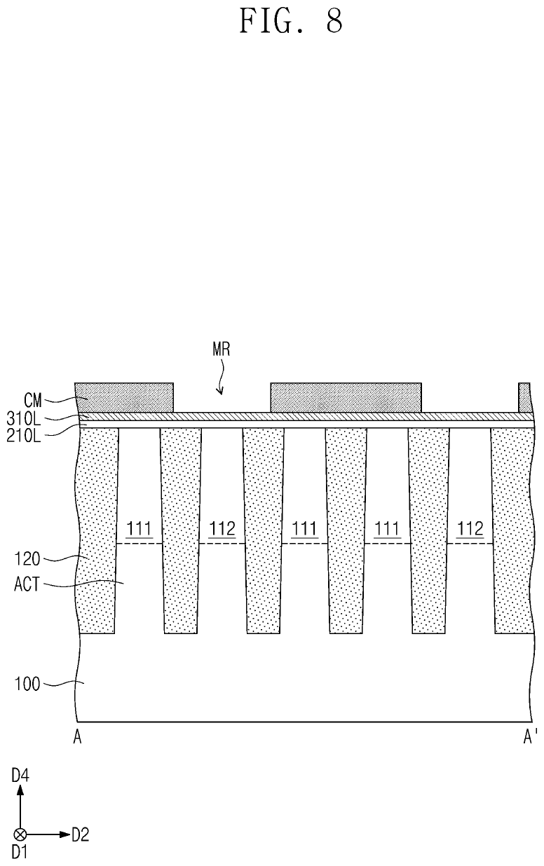

FIGS. 8 to 13 are sectional views illustrating a method of fabricating a semiconductor memory device according to an embodiment of the present disclosure. In detail, FIGS. 8 to 13 are sectional views taken along the line A-A′ of FIG. 2. Hereinafter, a semiconductor fabricating method according to an embodiment of the present disclosure will be described with reference to FIGS. 8 to 13. For concise description, a previously-described element may be identified by the same reference number without repeating an overlapping description thereof.

Referring to FIGS. 2 and 8, the substrate 100 may be prepared. The device isolation pattern 120, which is buried in an upper portion of the substrate 100, may be formed. The formation of the device isolation pattern 120 may include patterning the upper portion of the substrate 100 to form an isolation trench and forming the device isolation pattern 120 to fill the isolation trench. Remaining portions of the upper portion of the substrate 100, which are enclosed or surrounded by the device isolation pattern 120, may be defined as the active patterns ACT. Impurity regions may be formed in the active patterns ACT. The formation of the impurity regions may include injecting impurities into the active patterns ACT through an ion implantation process.

The word lines WL may be formed in trenches, which are formed in an upper portion of the substrate 100. The formation of the word lines WL may include forming mask patterns (not shown) on the active patterns ACT and the device isolation pattern 120, performing an anisotropic etching process using the mask patterns to form the trenches, and filling the trenches with the word lines WL. The word lines WL may be spaced apart from each other in the first direction D1 and may extend in the second direction D2 in the active patterns ACT. In an embodiment, the filling of the word lines WL may include conformally depositing the gate dielectric pattern GI on an inner surface of each of the trenches, filling the trenches with a conductive layer, performing an etch-back and/or polishing process on the conductive layer to form the gate electrode GE, and forming the gate capping pattern GC on the gate electrode GE to fill a remaining portion of the trench. A pair of the word lines WL may intersect the active pattern ACT, and the center portion 112 of the active pattern ACT may be defined between the pair of the word lines WL. The remaining portions of the active pattern ACT, which are spaced apart from the center portion 112 with each word line WL interposed therebetween, may be defined as the edge portions 111.

A buffer layer 210L and a polysilicon layer 310L may be sequentially formed on the substrate 100. The buffer layer 210L and the polysilicon layer 310L may be on and/or cover the top surface of the active pattern ACT, the top surface of the device isolation pattern 120, and the top surface of the word line WL.

A contact mask pattern CM may be formed on the polysilicon layer 310L. The contact mask pattern CM may include mask recess regions MR. In an embodiment, each of the mask recess regions MR may be formed on the center portion 112 of each of the active patterns ACT.

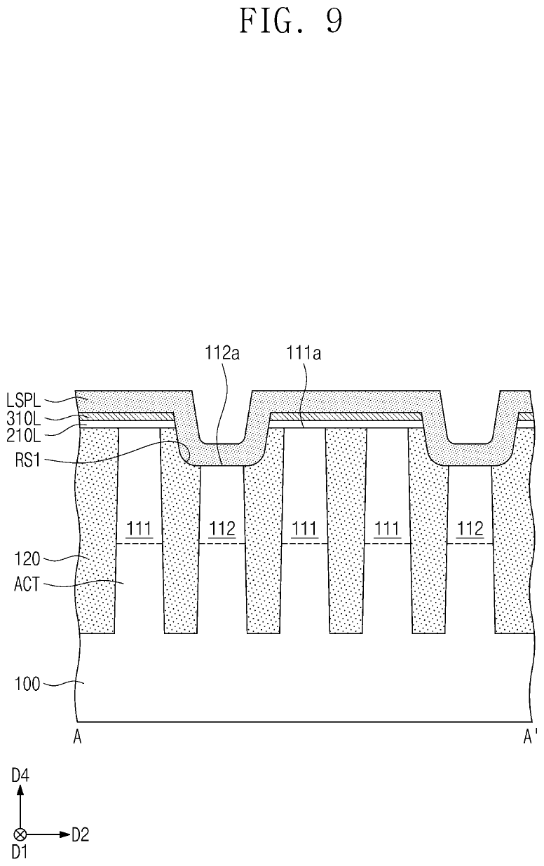

Referring to FIGS. 2 and 9, the first recess region RS1 may be formed on the center portion 112 of the active pattern ACT by performing an etching process using the contact mask pattern CM as an etch mask. The first recess region RS1 may be formed to extend through the buffer layer 210L and the polysilicon layer 310L and to expose a portion of the center portion 112 of the active pattern ACT, a portion of the device isolation pattern 120 adjacent to the center portion 112, and a portion of the gate capping pattern GC to the outside.

Hereinafter, a lower spacer layer LSPL may be formed on the first recess region RS1 and the polysilicon layer 310L. In an embodiment, the lower spacer layer LSPL may be formed to cover a top surface of the polysilicon layer 310L and an inner surface of the first recess region RS1. The formation of the lower spacer layer LSPL may include performing a chemical vapor deposition (CVD) or atomic layer deposition (ALD) process.

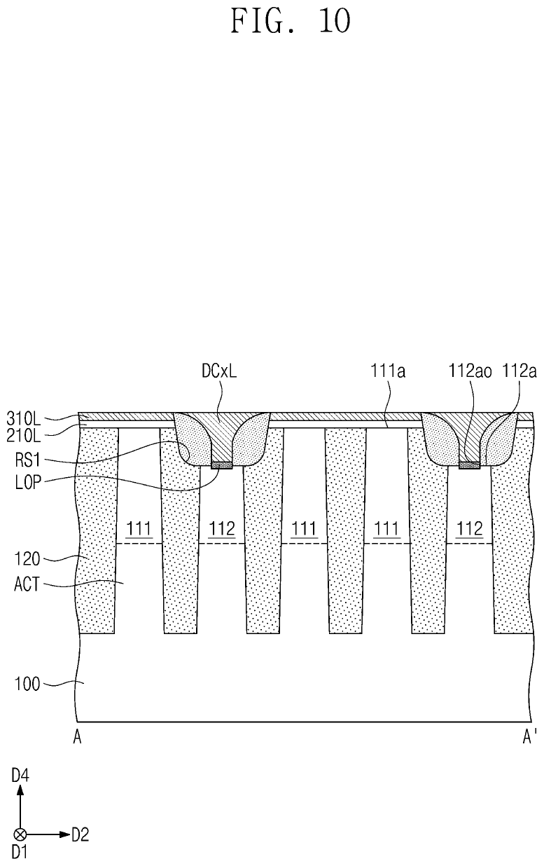

Referring to FIGS. 2 and 10, the lower spacer layer LSPL may be etched to form the lower spacer LSP in the first recess region RS1. The lower spacer LSP may cover a portion of an inner surface of the first recess region RS1. The top surface of the polysilicon layer 310L may be exposed to the outside. An open region 112ao may be formed on a top surface of the center portion 112 of the active pattern ACT. A portion of the top surface of the center portion 112 of the active pattern ACT may be exposed to the outside through the open region 112ao.

Next, the lower ohmic pattern LOP may be locally formed on the center portion 112 of the active pattern ACT. In an embodiment, the lower ohmic pattern LOP may be formed on the open region 112ao. The lower ohmic pattern LOP may be formed through a selective epitaxial growth process. The selective epitaxial growth process may be one of deposition methods growing a specific material on only a specific region. The lower ohmic pattern LOP may fill the open region 112ao.

According to an embodiment of the present disclosure, the first recess region RS1 may be formed on the center portion 112 of the active pattern ACT, before the formation of the lower spacer LSP. Here, in the case where the first recess region RS1 is formed at a misaligned position in the second direction D2, the edge portion 111 of the active pattern ACT, which is adjacent to the center portion 112 of the active pattern ACT, may be exposed through the first recess region RS1. The lower spacer LSP may cover the exposed edge portion 111 again, and the open region 112ao may be locally formed on the center portion 112 of the active pattern ACT. Thus, it may be possible to prevent or suppress a process failure, in which the lower ohmic pattern LOP is formed on the exposed edge portion 111, and as a result, the productivity of the semiconductor memory device may be improved.

Hereinafter, a lower bit line contact layer DCxL may be formed to fill each of the first recess regions RS1. The formation of the lower bit line contact layer DCxL may include forming a lower bit line contact layer (not shown) to cover the top surface of the polysilicon layer 310L and to fill a remaining portion of the first recess region RS1, and the formation may also include removing an upper portion of the lower bit line contact layer to expose the top surface of the polysilicon layer 310L. Since the upper portion of the lower bit line contact layer is removed, the lower bit line contact layer DCxL may be formed to fill each of the first recess regions RS1.

The formation of the lower bit line contact layer may include performing a chemical vapor deposition (CVD) process. The removal of the upper portion of the lower bit line contact layer may include performing a chemical mechanical planarization (CMP) process. A top surface of the lower bit line contact layer DCxL may be coplanar with the top surface of the polysilicon layer 310L. Since the upper portion of the lower bit line contact layer is removed, the top surface of the polysilicon layer 310L may be exposed to the outside.

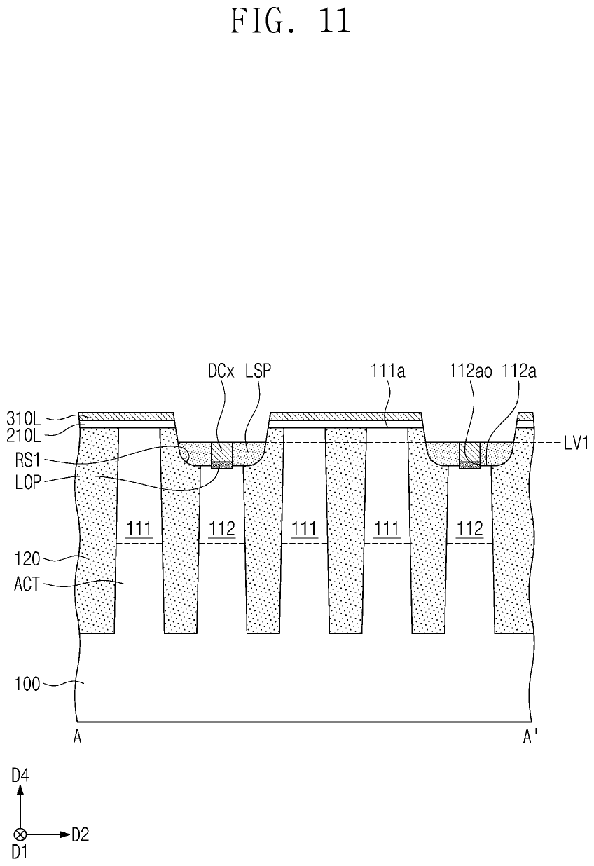

Referring to FIGS. 2 and 11, the lower portion DCx of the bit line contact DC may be formed on the center portion 112 of the active pattern ACT by etching the lower bit line contact layer DCxL. A top surface of the lower portion DCx of the bit line contact DC may be formed to be located at the first level LV1. An upper portion of the lower spacer layer LSPL may also be removed by the etching process. Accordingly, the top surface of the lower spacer LSP may be formed to be located at the first level LV1. The top surface of the lower portion DCx of the bit line contact DC may be formed to be coplanar with the top surface of the lower spacer LSP. As a result of the etching process, the polysilicon layer 310L, the buffer layer 210L, and the device isolation pattern 120 may be exposed through the first recess region RS1.

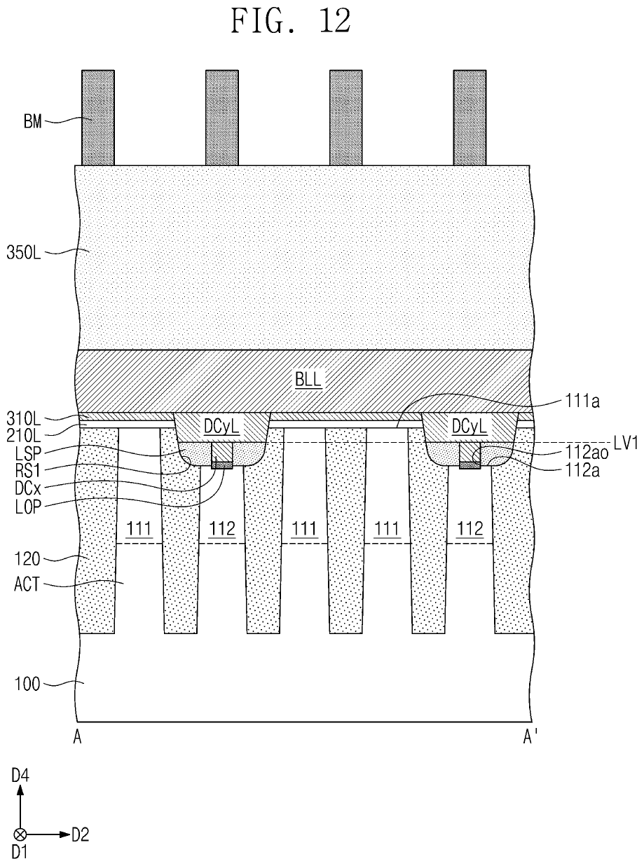

Referring to FIGS. 2 and 12, an upper bit line contact layer DCyL may be formed to fill each of the first recess regions RS1. The upper bit line contact layer DCyL may be formed in an upper portion of the first recess region RS1.

Next, a bit line layer BLL, a bit line capping layer 350L, and a bit line mask pattern BM may be sequentially formed on the substrate 100. The bit line mask pattern BM may include a plurality of line patterns, which are extended in the first direction D1 and are spaced apart from each other in the second direction D2. A width of the bit line mask pattern BM in the second direction D2 may be larger than a width W2 of the lower portion DCx of the bit line contact DC in the second direction D2. In an embodiment, a first ohmic layer (not shown) may be further formed between the bit line layer BLL and the polysilicon layer 310L.

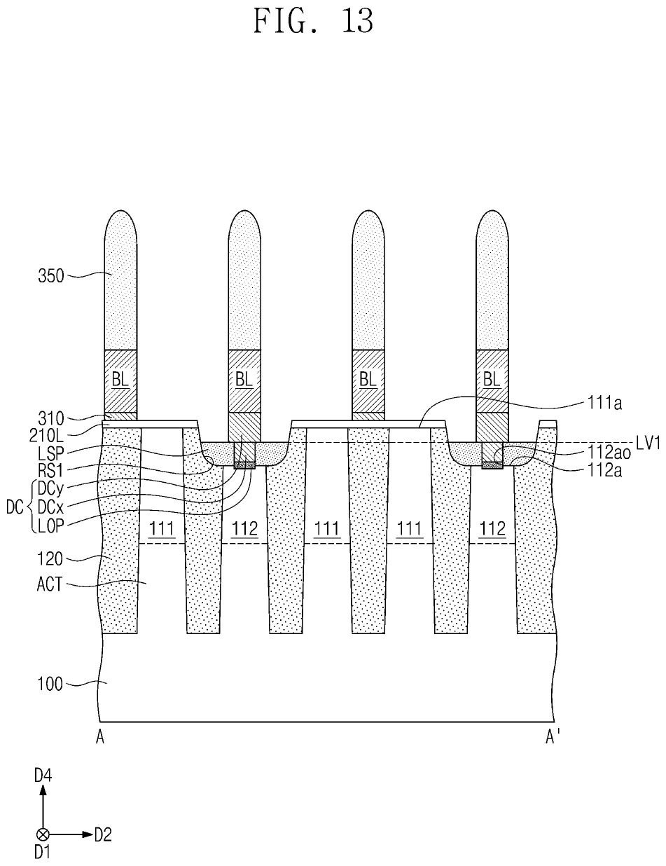

Referring to FIGS. 2 and 13, the bit line capping pattern 350, the bit line BL, the polysilicon pattern 310, and the upper portion DCy of the bit line contact DC may be formed. In an embodiment, the bit line capping pattern 350, the bit line BL, the polysilicon pattern 310, and the upper portion DCy of the bit line contact DC may be formed by etching the bit line capping layer 350L, the bit line layer BLL, the polysilicon layer 310L, and the upper bit line contact layer DCyL, respectively, using the bit line mask pattern BM as an etch mask. A width of the upper portion DCy of the bit line contact DC, which is measured in the second direction D2 at the first level LV1, may be larger than a width of the lower portion DCx of the bit line contact DC. In an embodiment, a first ohmic pattern (not shown) may be further formed between the bit line BL and the polysilicon pattern 310.

As a result of the etching process, an upper portion of the first recess region RS1 may be exposed to the outside. A portion of the top surface of the lower spacer LSP may be covered with the bit line contact DC, and another portion may be exposed to the outside. A portion of a top surface of the buffer layer 210L may be covered with the polysilicon pattern 310, and another portion may be exposed.

According to an embodiment of the present disclosure, the lower spacer LSP may be provided in the first recess region RS1, before the formation of the bit line BL. Thus, since a portion of the upper bit line contact layer DCyL is etched to a level of the top surface of the lower spacer LSP, which is a level higher than the lowest point of the first recess region RS1, the etching process may be easily performed. As a result, it may be possible to increase the productivity of a process of fabricating a semiconductor memory device.

Referring back to FIGS. 2 to 3B, the lower insulating pattern LIS may be formed to fill a remaining portion of the first recess region RS1. The formation of the lower insulating pattern LIS may include forming a lower insulating layer (not shown) to fill the remaining portion of the first recess region RS1 and cover the side surface of the bit line BL and the buffer layer 210L and etching the lower insulating layer to expose the bit line BL and the buffer layer 210L. In an embodiment, the lower insulating layer may be formed to conformally cover the side surface of the bit line BL. Since the lower insulating layer is etched to expose the bit line BL and the buffer layer 210L or an upper portion of the lower insulating layer is removed, the lower insulating layer may form the lower insulating patterns LIS, which are separated from each other.

The bit line spacer 360 may be formed to cover the side surface of the bit line BL and the side surface of the bit line capping pattern 350. The formation of the bit line spacer 360 may include sequentially forming the first spacer 362, the second spacer 364, and the third spacer 366 to conformally cover the side surface of the bit line BL and the bit line capping pattern 350.

The storage node contacts BC and the fence patterns (not shown) may be formed between adjacent ones of the bit lines BL. The storage node contacts BC and the fence patterns may be alternately arranged in the second direction D2. The storage node contact BC may fill a recess region, which is on a corresponding one of the edge portions 111 of the active patterns ACT, and may be connected to the corresponding edge portion 111. The fence patterns may be formed on the word lines WL.

The formation of the storage node contacts BC and the fence patterns may include forming storage node contact lines (not shown) to fill a space between adjacent ones of the bit lines BL and extend in the first direction D1, partially removing the storage node contact lines on the word line WL to form preliminary storage node contacts (not shown), forming the fence patterns in the removed regions, and removing upper portions of the preliminary storage node contacts to form the storage node contacts BC. The storage node contact BC may be a lower portion of the preliminary storage node contact, which is not removed by the above process.

In an embodiment, the formation of the storage node contacts BC and the fence patterns may include forming fence lines (not shown) to fill spaces between adjacent ones of the bit lines BL and extend in the first direction D1, partially removing the fence lines on the edge portions 111 of the active patterns ACT to form the fence patterns, and forming the storage node contact BC in the removed region.

An upper portion of the bit line spacer 360 may be partially removed during the formation of the storage node contacts BC. In this case, the capping spacer 370 may be additionally formed in a region, which is formed by removing the bit line spacer 360. Next, the second barrier pattern 410 may be formed to conformally cover the bit line spacer 360, the capping spacer 370, and the storage node contacts BC.

The landing pads LP may be formed on the storage node contacts BC. The formation of the landing pads LP may include sequentially forming a landing pad layer (not shown) and mask patterns (not shown) to cover top surfaces of the storage node contacts BC and dividing the landing pad layer into a plurality of landing pads LP through an anisotropic etching process using the mask patterns as an etch mask. Additionally, the second barrier pattern 410, the bit line spacer 360, and the bit line capping pattern 350 may be partially etched through an etching process and may be exposed to the outside.

In an embodiment, the second spacer 364 may be exposed to the outside through the etching process of the landing pad layer. An etching process on the second spacer 364 may be further performed through the exposed portion of the second spacer 364, and in this case, the second spacer 364 may include an air gap. However, the present disclosure is not limited to this example.

Thereafter, the filler pattern 440 may be formed to cover the exposed portions and to surround/enclose each of the landing pads LP, and the data storage patterns DSP may be formed on the landing pads LP, respectively.

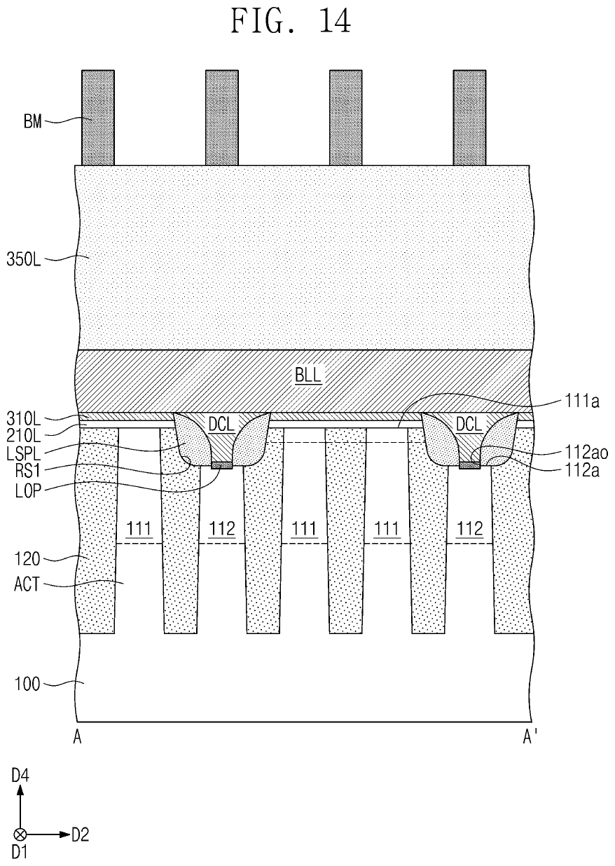

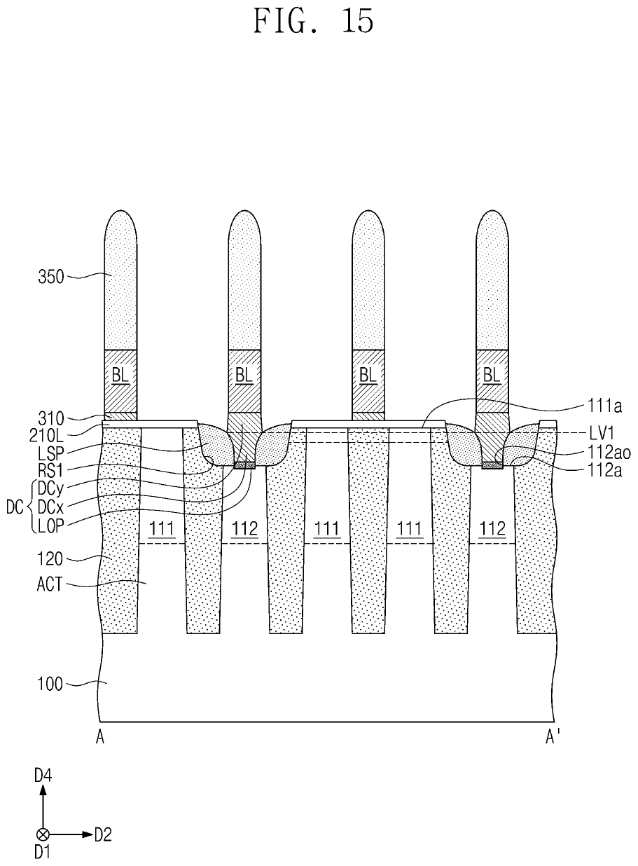

FIGS. 14 and 15 are sectional views illustrating a method of fabricating a semiconductor memory device according to an embodiment of the present disclosure. In detail, FIGS. 14 and 15 are sectional views taken along the line A-A′ of FIG. 2. Hereinafter, a method of fabricating a semiconductor memory device according to an embodiment of the present disclosure will be described in more detail with reference to FIGS. 14 and 15. For concise description, a previously-described element may be identified by the same reference number without repeating an overlapping description thereof.

Referring to FIG. 14, the bit line layer BLL, the bit line capping layer 350L, and the bit line mask pattern BM may be sequentially formed on the substrate 100, after the forming process of the bit line contact lines DCL described with reference to FIG. 10. In an embodiment, the bit line layer BLL, the bit line capping layer 350L, and the bit line mask pattern BM may be formed by a method similar to the process described with reference to FIG. 12.

Referring to FIG. 15, the bit line capping pattern 350, the bit line BL, the polysilicon pattern 310, and the bit line contact DC may be formed by an etching process using the bit line mask pattern BM as an etch mask. In an embodiment, the etching process may include a single step or a plurality of process steps (e.g., first and second etching steps). For example, the bit line capping pattern 350 and the bit line BL may be formed through the first etching step. In this case, a portion of a top surface of each of the bit line contact line DCL and the polysilicon layer 310L may be covered with the bit line BL, and the other portion may be exposed to the outside. The polysilicon pattern 310 and the bit line contact DC may be formed through the second etching step. In this case, the side surface of the bit line contact DC and an upper portion of the lower spacer LSP may be exposed to the outside. As an example, a width (e.g., W1 or W2) of the bit line contact DC measured in the second direction D2 at the first level LV1 may be larger than the fifth and sixth widths W5 and W6 of the bottom and top surfaces of the bit line contact DC. The lower spacer LSP may be at a level lower than the top surface of the buffer layer 210L. A portion of the top surface of the buffer layer 210L may be covered with the polysilicon pattern 310, and the other portion may be exposed to the outside. Next, a semiconductor memory device may be fabricated by a method similar to that in the embodiment of FIGS. 2 to 3B. Here, the fabricated semiconductor memory device may have substantially the same features as those of the semiconductor memory device described with reference to FIGS. 6 and 7.

According to an embodiment of the present disclosure, a bit line contact may be formed of or include a metallic material. Thus, the bit line contact may have a low resistance value, and as a result, the electrical and reliability characteristics of the semiconductor memory device may be improved.

In addition, a lower spacer may be provided to prevent a process failure in which an ohmic pattern is formed on an edge portion of an active pattern due to misalignment of a recess region. As a result, the productivity in a process of fabricating a semiconductor memory device may be improved.

While example embodiments of the present disclosure have been particularly shown and described, it will be understood by one of ordinary skill in the art that variations in form and detail may be made therein without departing from the spirit and scope of the attached claims.

What is claimed is:

1. A semiconductor memory device, comprising:
an active pattern on a substrate and at least partially surrounded by a device isolation pattern;
a bit line that extends on a center portion of the active pattern in a first direction that is parallel to a bottom surface of the substrate; and
a bit line contact between the bit line and the active pattern,
wherein the bit line contact comprises a metallic material,
wherein a width of the bit line contact at a first level and in a second direction is greater than a width of a bottom surface of the bit line contact in the second direction,
wherein the second direction intersects the first direction, and
wherein the first level is between a top surface of the device isolation pattern and the substrate.

2. The semiconductor memory device of claim 1, wherein a width of a top surface of the bit line contact in the second direction is greater than the width of the bottom surface of the bit line contact in the second direction.

3. The semiconductor memory device of claim 1, further comprising a lower spacer that is below the first level and on a portion of a side surface of the bit line contact.

4. The semiconductor memory device of claim 3, wherein the lower spacer comprises at least one of SiN, SiOCN, SiO₂, SiOC, and SiBN.

5. The semiconductor memory device of claim 1, further comprising a lower insulating pattern on a portion of a side surface of the bit line contact at a second level higher than the first level.

6. The semiconductor memory device of claim 1, further comprising a lower ohmic pattern between the bit line contact and the active pattern, wherein the lower ohmic pattern comprises a metal silicide material.

7. The semiconductor memory device of claim 6, wherein a bottom surface of the lower ohmic pattern is below an uppermost surface of the center portion of the active pattern.

8. The semiconductor memory device of claim 1, wherein the width of the bit line contact at the first level and in the second direction is greater than or equal to a width of a top surface of the bit line in the second direction.

9. The semiconductor memory device of claim 1, wherein the width of the bit line contact at the first level and in the second direction is less than a width of an uppermost surface of the center portion of the active pattern in the second direction.

10. A semiconductor memory device, comprising:
an active pattern on a substrate and at least partially surrounded by a device isolation pattern;
a bit line that extends on a center portion of the active pattern in a first direction that is parallel to a bottom surface of the substrate; and
a bit line contact between the bit line and the active pattern, the bit line contact comprising a metallic material,
wherein the bit line contact comprises an upper portion and a lower portion,
wherein the upper portion and the lower portion contact each other at a first level,
wherein a width of the upper portion at the first level and in a second direction is greater than a width of the lower portion at the first level and in the second direction,
wherein the second direction intersects the first direction.

11. The semiconductor memory device of claim 10, wherein a width of the lower portion of the bit line contact at the first level and in the second direction is greater than a width of a bottom surface of the lower portion of the bit line contact in the second direction.

12. The semiconductor memory device of claim 10, further comprising a lower spacer on a side surface of the lower portion of the bit line contact, wherein the lower spacer is between a top surface of the device isolation pattern and the substrate.

13. The semiconductor memory device of claim 12, wherein a width of the lower spacer in the second direction decreases toward the substrate.

14. The semiconductor memory device of claim 12, wherein a top surface of the lower spacer contacts a bottom surface of the upper portion of the bit line contact.

15. The semiconductor memory device of claim 12, wherein a bottom surface of the upper portion of the bit line contact covers a portion of a top surface of the lower spacer.

16. The semiconductor memory device of claim 10, further comprising a lower insulating pattern on a side surface of the upper portion of the bit line contact, wherein a bottom surface of the lower insulating pattern is coplanar with a bottom surface of the upper portion of the bit line contact.

17. A semiconductor memory device, comprising:
an active pattern on a substrate and at least partially surrounded by a device isolation pattern;
a bit line that extends on a center portion of the active pattern in a first direction that is parallel to a bottom surface of the substrate; and
a bit line contact between the bit line and the active pattern,
wherein the bit line contact comprises a metallic material,
wherein a width of the bit line contact at a first level and in a second direction is greater than a width of a bottom surface of the bit line contact in the second direction and a width of a top surface of the bit line contact in the second direction,
wherein the second direction intersects the first direction.

18. The semiconductor memory device of claim 17, wherein the width of the bit line contact at the first level and in the second direction is greater than a width of a top surface of the bit line in the second direction.

19. The semiconductor memory device of claim 17, further comprising:
a lower spacer below the first level and on a portion of a side surface of the bit line contact; and
a lower insulating pattern above the first level and on another portion of the side surface of the bit line contact.

20. The semiconductor memory device of claim 19, wherein the lower insulating pattern contacts the lower spacer above the first level.
